(19) United States
(12) Patent Application Publication
(10) Pub. No.: US 2023/0413440 A1
(43) Pub. Date: Dec. 21, 2023

(54) Cavity-Stacked Printed Circuit Board Assemblies

(71) Applicant: Google LLC, Mountain View, CA (US)

(72) Inventors: Jiali Lai, Rolling Meadows, IL (US); Naiyong Chen, Hayward, CA (US); ChanWei Chiu, Taoyuan City (TW); Joseph L. Allore, Mundelein, IL (US); Michael J. Lombardi, South Barrington, IL (US)

(73) Assignee: Google LLC, Mountain View, CA (US)

(21) Appl. No.: 18/462,212

(22) Filed: Sep. 6, 2023

Related U.S. Application Data
(60) Provisional application No. 63/580,593, filed on Sep. 5, 2023.

(51) Int. Cl. H05K 1/14; H05K 1/18

(52) U.S. Cl. CPC H05K 1/141; H05K 1/181; H05K 2201/10378; H05K 2201/10734

(57) ABSTRACT

Disclosed is a cavity-stacked printed circuit board (PCB) assembly that includes a first PCB formed of glass-reinforced epoxy material and has a first and a second side. The first side includes an open cavity with a cavity floor and at least one side wall that extends between the floor and the first side. The open cavity defines a cavity perimeter, which includes a base defined around the perimeter. The second PCB has a top side opposite a bottom side. The top side has an electrical component around which an interposer region is defined. Solder is disposed between the interposer region of the second PCB and the base of the first PCB to couple the first PCB to the second PCB with the electrical component received in the cavity to form the cavity-stacked PCB assembly.

### CROSS-REFERENCE TO RELATED APPLICATION(S)

This application claims priority to U.S. Provisional Patent Application Ser. No. 63/580,593 filed on Sep. 5, 2023, the disclosures of which are incorporated by reference herein in their entireties.

### SUMMARY

This document describes techniques and apparatuses directed to cavity-stacked printed circuit board (PCB) assemblies. This document also describes methods for the fabrication of cavity-stacked PCB assemblies and apparatuses including cavity-stacked PCB assemblies.

In some aspects, the apparatuses described herein relate to a cavity-stacked PCB assembly that includes a first PCB formed of a glass-reinforced epoxy material and a second PCB formed of a glass-reinforced epoxy material. The second PCB has a top side opposite a bottom side and an electrical component disposed on the top side. The second PCB defines an interposer region around the electrical component. The first PCB has a first side opposite a second side. The first side includes an open cavity cut in the glass-reinforced epoxy material. The open cavity includes a cavity floor and at least one side wall. The side wall extends between the cavity floor and the first side and defines a cavity perimeter. The first PCB includes a base defined around the cavity perimeter. Solder is disposed between the interposer region of the second PCB and the base of the first PCB to couple the first PCB to the second PCB with the electrical component received in the cavity.

In some aspects, the apparatuses described herein relate to a cavity-stacked PCB assembly, wherein the second PCB is also formed of the glass-reinforced epoxy material, the first PCB has a first thickness, the second PCB has a second thickness, and the first thickness is greater than the second thickness.

In some aspects, the apparatuses described herein relate to a cavity-stacked PCB assembly that further includes an underfill aperture extending between the second side and the cavity.

In some aspects, the apparatuses described herein relate to a cavity-stacked PCB assembly that further includes underfill dispensed through the underfill aperture and into the cavity, the underfill flowed under and around the electrical component received in the cavity.

In some aspects, the apparatuses described herein relate to a cavity-stacked PCB assembly, wherein at least one of the interposer region of the second PCB or the base of the first PCB includes at least one surface mount technology (SMT) spacer configured for controlling spacing between the first PCB and the second PCB.

In some aspects, the apparatuses described herein relate to a cavity-stacked PCB assembly, wherein the first PCB and the second PCB are positioned in parallel planes.

In some aspects, the apparatuses described herein relate to a cavity-stacked PCB assembly, wherein the side wall is orthogonal to the first side.

This Summary is provided to introduce simplified concepts of cavity-stacked PCB assemblies, which are further described below in the Detailed Description and are illustrated in the Drawings. This Summary is intended neither to identify essential features of the claimed subject matter nor for use in determining the scope of the claimed subject matter.

### BRIEF DESCRIPTION OF THE DRAWINGS

The details of one or more aspects of cavity-stacked printed circuit board (PCB) assemblies are described in this document with reference to the following drawings, wherein the use of same numbers in different instances may indicate similar features or components:

FIG. 1 is a schematic illustration of a first PCB including cavities;

FIG. 2 is a schematic illustration of the first PCB of FIG. 1, including modules and shielding;

FIG. 3 is a schematic illustration of a second PCB with modules and shielding on a top side;

FIG. 4 is a schematic illustration of the second PCB of FIG. 3, with modules on a bottom side;

FIG. 5 is a schematic illustration of the first PCB of FIG. 2 and the second PCB of FIG. 3 connected together to form a PCB assembly;

FIG. 6 is a schematic illustration of the PCB assembly of FIG. 5 including underfill; and

FIG. 7 is a schematic illustration of the PCB assembly of FIG. 6 with a shielding layer.

### DETAILED DESCRIPTION

Overview

This document describes techniques and apparatuses directed to cavity-stacked printed circuit board (PCB) assemblies. This document also describes methods for the fabrication of cavity-stacked PCB assemblies and apparatuses including cavity-stacked PCB assemblies.

A PCB may be formed from a glass-reinforced epoxy material (e.g., FR4). In some instances, a PCB may include a single layer of electrically conductive traces and be a single-layer board. In other instances, a PCB may be a multi-layer board (MLB) that includes multiple layers of electrically conductive traces that are separated by layers of a dielectric material.

The disclosed cavity-stacked PCB assemblies may include a first PCB and a second PCB, with the first PCB thicker than the second PCB. The first PCB has a first side, and a cut may be formed in the first side of the first PCB to form at least one cavity. The first PCB and the second PCB can be stacked and soldered together to form a cavity-stacked PCB assembly (e.g., a cavity-stacked MLB assembly) that does not include a traditional interposer that extends between the first PCB and the second PCB. By so doing, in some cases, the techniques may simplify surface mount technology (SMT) processes, may increase the yield, and/or may lower the cost of production.

In aspects, the cavity-stacked PCB assemblies are cavity-stacked MLB assemblies. A “main logic board” may be a main PCB of a computing device and may include one or more PCBs.

Cavity-Stacked Printed Circuit Board Assemblies

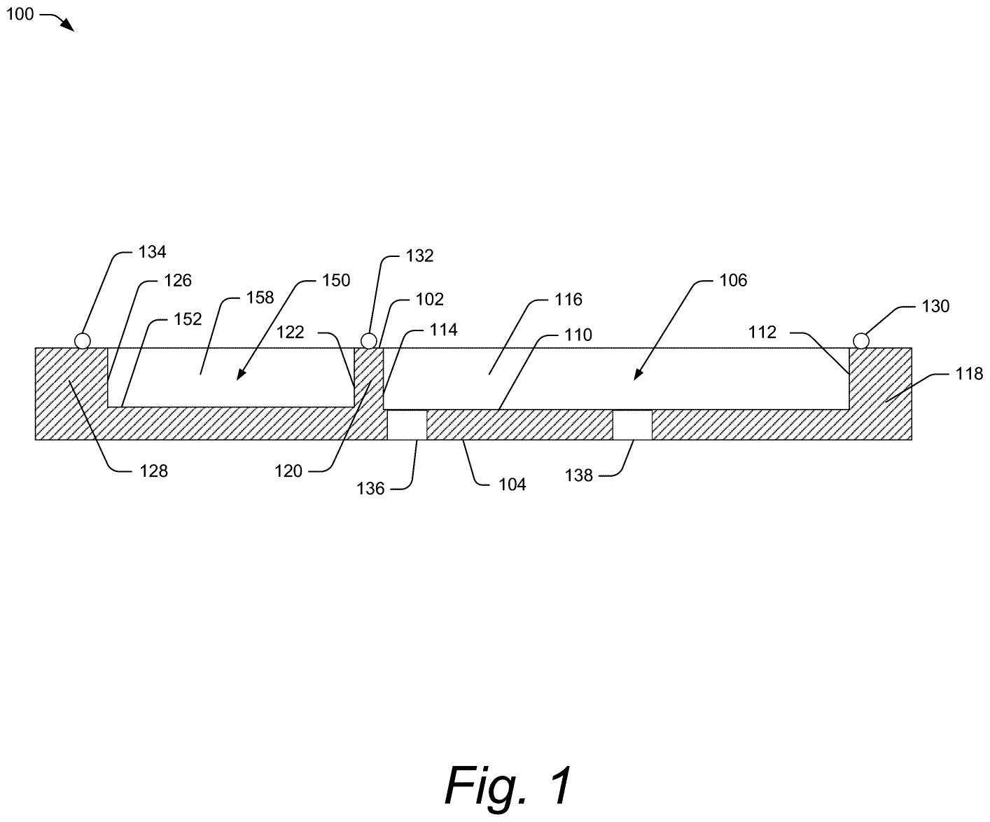

FIGS. 1-7 are schematic illustrations that show the fabrication of an example cavity-stacked PCB assembly. Referring initially to FIG. 1, illustrated is a first PCB 100 (e.g., a cavity module). The first PCB 100 may be thicker than a traditional PCB. The first PCB 100 has a first side 102 opposite a second side 104. At least one cavity is defined in the first side 102. For example, a first cavity 106 and a second cavity 150 may be formed in the first side 102 through a laser cutting process, a machining (e.g., computer numerical control (CNC) machining) process, and the like. In aspects, a cavity may be formed as one or more of a through cut, a blind cut (aka a stopped cut), a mortise cut, or another type of fabrication process.

The first cavity 106 is defined between a first cavity floor 110 and at least one wall of an upright (e.g., side wall, end wall). The first PCB 100 includes a first side wall 112 opposite a second side wall 114 and a first end wall 116 opposite a second end wall (not illustrated). The first side wall 112 is defined on a first upright 118, the second side wall 114 and a third side wall 122 are defined on a second upright 120, and a fourth side wall 126 is defined on a third upright 128. The side walls (e.g., first side wall 112, second side wall 114, third side wall 122, fourth side wall 126) are orthogonal to the first side 102. The second cavity 150 is defined between a cavity floor 152 and at least one wall (e.g., the third side wall 122 opposite the fourth side wall 126 and a third end wall 158 opposite a fourth end wall (not illustrated)).

One or more underfill orifices configured to receive a nozzle of an underfill dispenser may be defined through the first PCB 100. For example, a first underfill orifice 136 and a second underfill orifice 138 may extend between the second side 104 and the first cavity floor 110 in the first cavity 106.

Solder (e.g., high-temperature solder paste) may be applied to one or more bases of the uprights in an interposer region during a pre-solder process. For example, solder 130 may be added to a base of the first upright 118, solder 132 may be added to a base of the second upright 120, and solder 134 may be added to a base of the third upright 128. The application process may include printing and/or using stenciling.

In aspects, solder paste may be used for surface mounting. Several types of surface-mounting may be used when securing an integrated circuit to a device such as a PCB, including a ball grid array (BGA), micro ball grid array (pBGA), or land grid array (LGA).

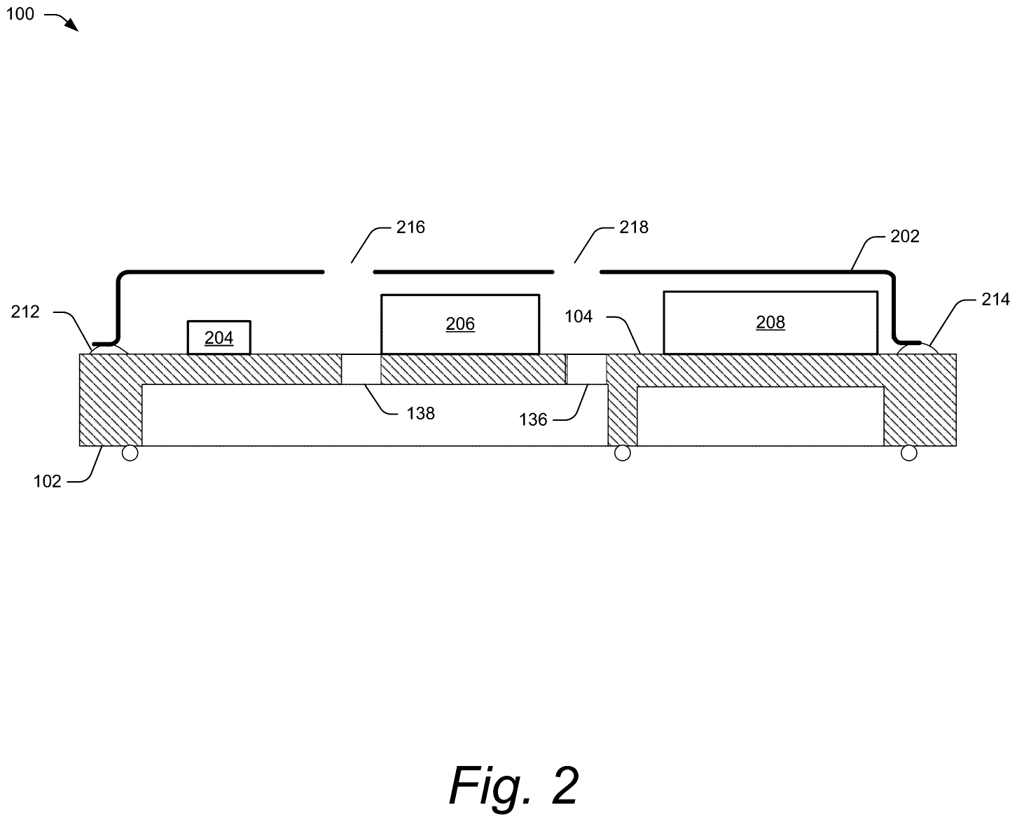

FIG. 2 depicts the first PCB 100 illustrated rotated 180 degrees relative to the illustration in FIG. 1. One or more electronic components (e.g., integrated circuit chip, transceiver chip, system-on-chip (SoC), central processing unit (CPU), antenna, board-to-board connector) are disposed on the first PCB 100. For example, a component 204, component 206, and component 208 may be soldered or otherwise attached to the second side 104 of the first PCB 100. The electronic components may be SMT components.

Electromagnetic interference (EMI) shielding 202 may be attached to the second side 104 of the first PCB 100, for example, through soldering (e.g., solder 212, solder 214). One example of EMI shielding 202 is a component radiation shield that forms an electromagnetic shield, which may be installed on the PCB over the electronic components to mitigate EMI. One or more underfill apertures (e.g., underfill aperture 216, underfill aperture 218) may be defined through the EMI shielding 202. The underfill apertures may be configured to provide access to the shielded electronic components and/or to the underfill orifice(s) (e.g., first underfill orifice 136, second underfill orifice 138) defined through the first PCB 100.

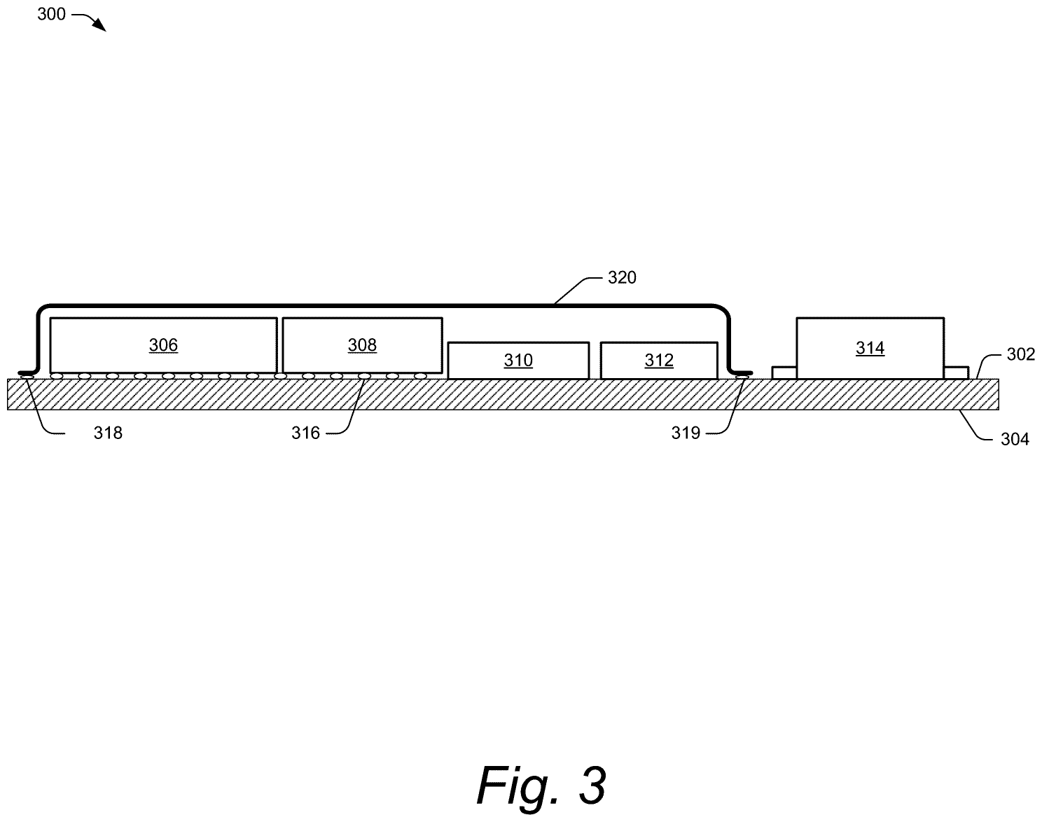

FIG. 3 illustrates a second PCB 300 (e.g., a main board) with a top side 302 opposite a bottom side 304 and electronic components (e.g., component 306, component 308, component 310, component 312, component 314) disposed on the top side 302. The electronic components may be located within an EMI shield 320 and may be SMT components. The electronic components and/or EMI shield 320 may be attached to the second PCB 300 through solder (e.g., solder 316, solder 318, solder 319).

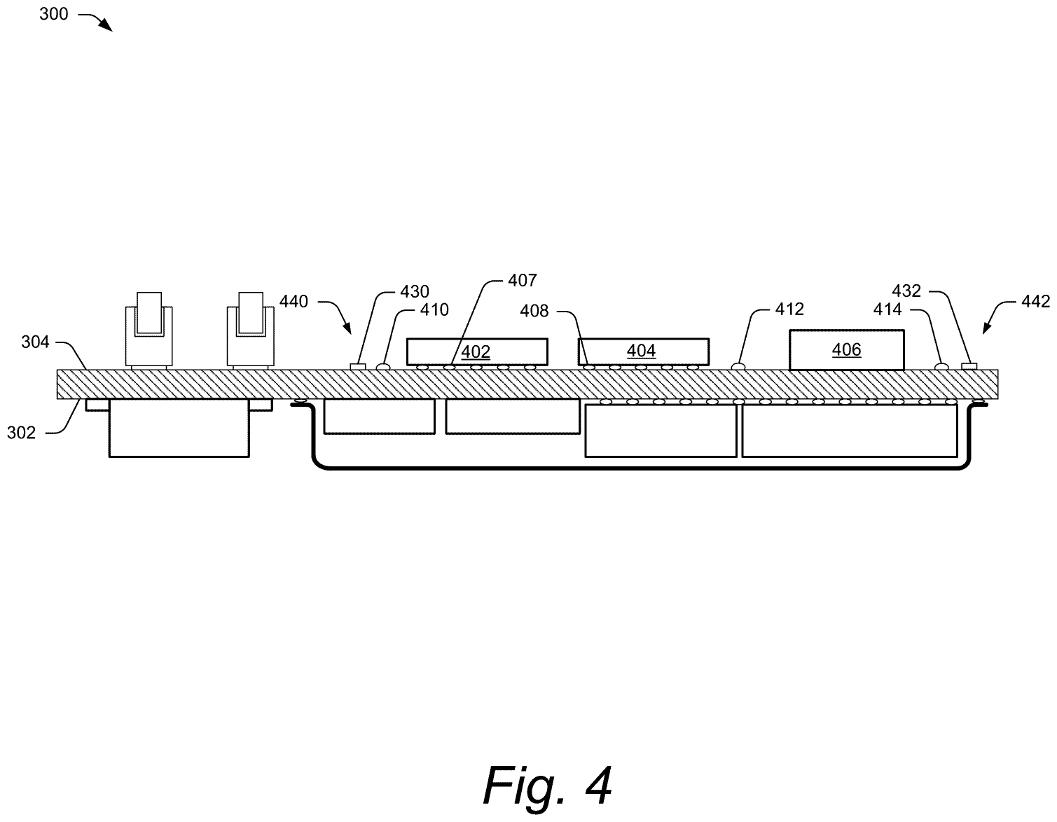

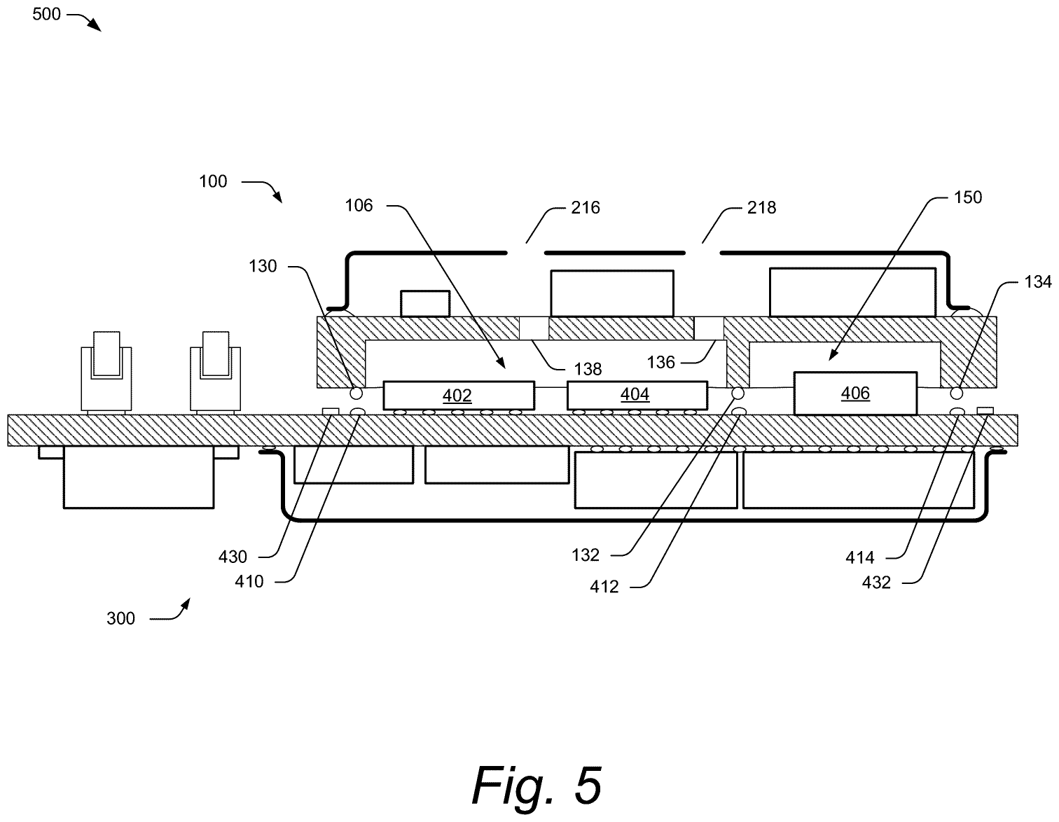

FIG. 4 illustrates the second PCB 300 rotated 180 degrees relative to the second PCB 300 of FIG. 3 and includes additional electronic components (e.g., component 402, component 404, component 406) positioned on the bottom side 304 of the second PCB 300. The electronic components may be SMT components. The electronic components may be connected to the bottom side 304 of the second PCB 300 through solder (e.g., solder 407, solder 408). Additional solder (e.g., solder 410, solder 412, solder 414) may be added to the bottom side 304 of the second PCB 300 during a pre-solder process, with the solder positioned for connection of the second PCB 300 with the first PCB 100, as illustrated in FIG. 5.

When the components are placed (e.g., via SMT), one or more spacers (e.g., spacer 430, spacer 432) may also be placed within an interposer region (e.g., interposer region 440, interposer region 442). An interposer region may be defined as a perimeter region of a stacked PCB assembly (described in FIG. 5). The spacers are configured for controlling the gap between the first PCB 100 and the second PCB 300. In aspects, a spacer is a metal circular puck having a 0.1 mm thickness. In other aspects, the spacer may be of another material and/or of a different size/shape. The spacers and the interposer region may establish electrical connections between the first PCB 100 and the second PCB 300, providing a pathway for power, signals, and ground connections between the two PCBs 100 and 300.

FIG. 5 depicts the first PCB 100 and the second PCB 300 positioned together to form a stacked PCB assembly 500 (e.g., cavity-stacked PCB, cavity-stacked MLB). The first PCB 100 and the second PCB 300 are positioned in parallel planes. One or more of the electronic components on the bottom side 304 of the second PCB 300 are positioned to be received within a cavity (e.g., first cavity 106, second cavity 150) of the first PCB 100. After positioning, a reflow process may be performed to form solder connections between the first PCB 100 and the second PCB 300 (e.g., between solder 130 and solder 410, between solder 132 and solder 412, between solder 134 and solder 414) to form the stacked PCB assembly 500. In aspects, a final visual inspection (e.g., an AOI) may occur after the reflow process.

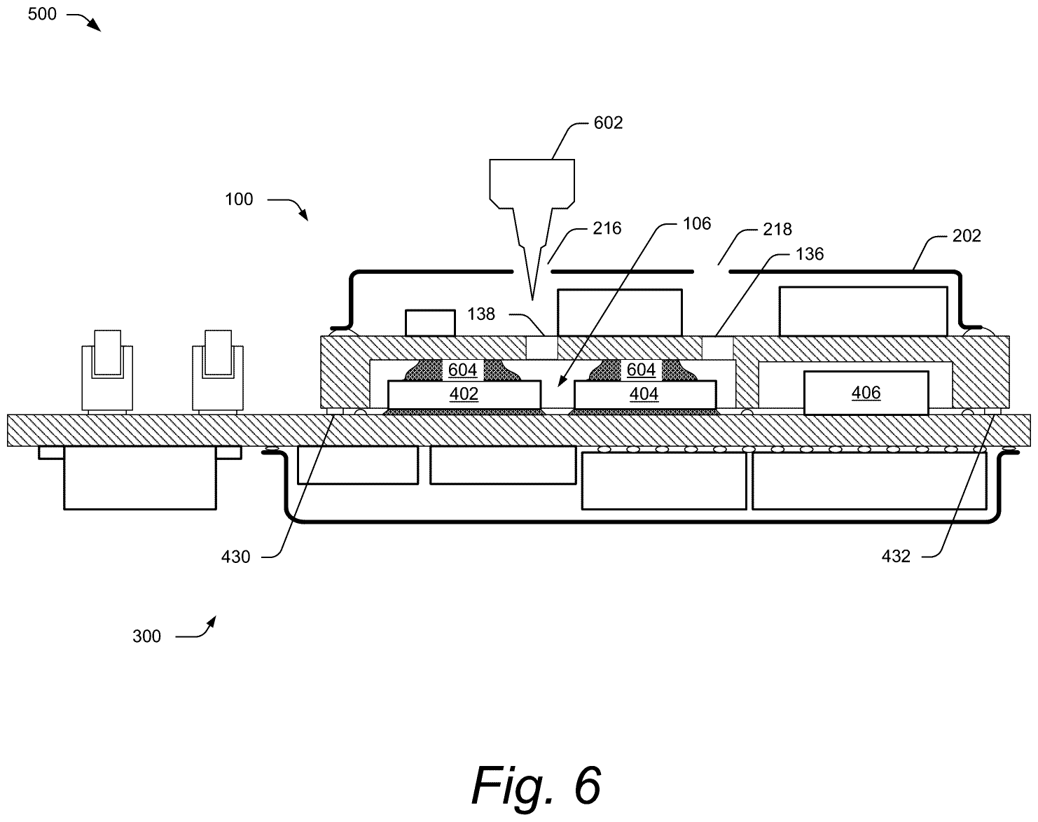

FIG. 6 illustrates the stacked PCB assembly 500 after the reflow process, with dispensed underfill 604. The underfill 604 may be dispensed onto the components within the first cavity 106 of the stacked PCB assembly 500 through the second underfill orifice 138. For example, an underfill dispensing nozzle 602 may be positioned within an underfill aperture (e.g., underfill aperture 216, underfill aperture 218) of the first PCB 100 and underfill 604 may be dispensed from the underfill dispensing nozzle 602 into a cavity (e.g., first cavity 106). In securing a surface-mounted integrated circuit to a device such as a PCB, underfill is sometimes used to further secure a mechanical connection between the integrated circuit and the device. The underfill typically includes a low-viscosity suspension, such as a polymer, a curable polymer, a filling material, an epoxy, or another glue. The underfill may reinforce a mechanical connection provided by a ball grid array (BGA) or land grid array (LGA) of solder balls in securing the integrated circuit to the device. The dispensing nozzle (e.g., the underfill dispensing nozzle 602) mayjet a quantity of underfill adjacent to a mounting location where the integrated circuit is soldered to the device. By capillary action, the underfill is drawn beneath the integrated circuit and around the BGA or LGA. The underfill, once cured, encapsulates the BGA or LGA and supports mechanical and electrical connections between the integrated circuit and the device to protect the integrity of the connections when the device including the integrated circuit is dropped and/or during thermal cycling of the device.

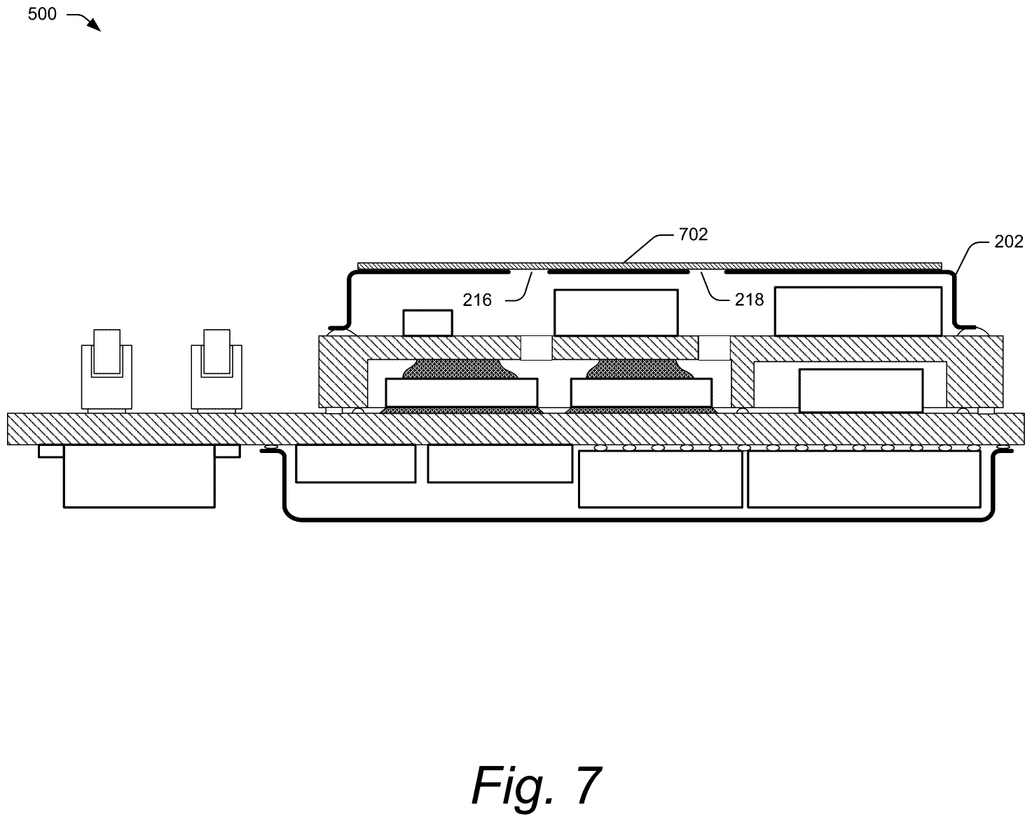

FIG. 7 illustrates the stacked PCB assembly 500 with the underfill aperture 216 and underfill aperture 218 of the EMI shielding 202 covered with a shielding layer 702 (e.g., adhesive metallic foil tape, adhesive shielding tape) to prevent RF radiation from passing through the underfill aperture(s). The shielding layer 702 may be implemented in the form of an adhesive shielding tape, a metallic foil tape (e.g., copper foil), or the like. The shielding layer 702 may also prevent external debris, dust, and/or moisture from interfering with the function of the stacked PCB assembly 500.

In aspects, a stacked PCB assembly may be incorporated into a computing device (e.g., smartphone, tablet computer, camera, computer, smart watch, intelligent glasses, wearable device). The term “wearable device,” as used in this disclosure, refers to any device that is capable of being worn at, on, or in proximity to a person's body (e.g., wrist, ankle, waist, chest, other body part) or prosthetic (e.g., watch, bracelet, ring, necklace, other jewelry, eyewear, footwear, glove, headwear, clothing, goggles, contact lens).

Example Methods

This section describes example methods for the fabrication of a cavity-stacked PCB assembly, which includes operations that may operate separately or together in whole or in part.

In a general, first aspect, the present disclosure relates to a method for fabrication of a cavity-stacked PCB assembly. In a first operation, a first PCB having a first side opposite a second side is provided. A cavity defined by at least one cavity wall is formed in the first side. High-temperature solder paste is applied in an interposer region to a base of at least one cavity wall. An area outside of the cavity, on the first side of the first PCB, may then be populated with one or more modules. The second side of the first PCB may also be populated with one or more modules, which may include the population of one or more modules on the PCB opposite the cavity. A second PCB (e.g., or a main board) may be provided, the second PCB having a top side opposite a bottom side. The top and bottom sides of the second PCB may then be populated with modules. This population process may include the population of one or more modules on the bottom side of the second PCB. High-temperature solder paste is applied to the bottom side of the second PCB. The first PCB and the second PCB are then arranged together so that the second side of the first PCB is mated with the bottom side of the second PCB, with a cavity component received in the cavity. A reflow process is then performed to form solder connections between the first PCB and the second PCB.

This document also describes optional aspects that may include one or more of the following features. The first PCB may define at least one underfill aperture through the first PCB in the cavity. Underfill material may be dispensed through the underfill aperture, the underfill material configured to flow under and around the at least one cavity component. The application of high-temperature solder paste to a base of the at least one cavity wall in an interposer region may include inserting a plurality of SMT spacers in the interposer region, the SMT spacers configured for controlling the spacing between the first PCB and the second PCB. The first and second PCBs may be positioned in parallel planes. Optional features of one aspect, such as one of the methods described above, may be combined with other aspects.

### CONCLUSION

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

Although concepts of techniques and apparatuses, including the fabrication of cavity-stacked PCB assemblies, have been described in language specific to techniques and/or apparatuses, it is to be understood that the subject of the appended claims is not necessarily limited to the specific techniques or apparatuses described. Rather, the specific techniques and apparatuses are disclosed as example implementations of ways in which fabrication of cavity-stacked PCB assemblies may be implemented.

What is claimed is:

1. A cavity-stacked printed circuit board (PCB) assembly comprising:
a first PCB, the first PCB formed of a glass-reinforced epoxy material, the first PCB having a first side opposite a second side, the first side including an open cavity cut in the glass-reinforced epoxy material, the open cavity including a cavity floor and at least one side wall, the at least one side wall extending between the cavity floor and the first side, the open cavity defining a cavity perimeter, the first PCB including a base defined around the cavity perimeter;
a second PCB, the second PCB having a top side opposite a bottom side, the second PCB having an electrical component disposed on the top side, the second PCB defining an interposer region defined around the electrical component; and
solder disposed between the interposer region of the second PCB and the base of the first PCB, the solder coupling the first PCB to the second PCB, the electrical component at least partially received in the open cavity.

2. The cavity-stacked PCB assembly of claim 1, wherein the second PCB is also formed of the glass-reinforced epoxy material, the first PCB has a first thickness, the second PCB has a second thickness, and the first thickness is greater than the second thickness.

3. The cavity-stacked PCB assembly of claim 1, further comprising:
an underfill aperture extending between the second side and the open cavity.

4. The cavity-stacked PCB assembly of claim 3, further comprising:
underfill dispensed through the underfill aperture and into the open cavity, the underfill flowed under and around the electrical component.

5. The cavity-stacked PCB assembly of claim 1, wherein at least one of the interposer region of the second PCB or the base of the first PCB includes at least one surface mount technology spacer configured for controlling spacing between the first PCB and the second PCB.

6. The cavity-stacked PCB assembly of claim 1, wherein the first PCB and the second PCB are positioned in parallel planes.

7. The cavity-stacked PCB assembly of claim 1, wherein the side wall is orthogonal to the first side.
